(19) United States
(12) Patent Application Publication
(10) Pub. No.: US 2017/0140704 A1
(43) Pub. Date: May 18, 2017

(54) AMOLED PIXEL DRIVING CIRCUIT AND PIXEL DRIVING METHOD

(71) Applicant: Shenzhen China Star Optoelectronics Technology Co. Ltd., Shenzhen City (CN)

(72) Inventor: Yuying Cai, Shenzhen City (CN)

(21) Appl. No.: 14/778,615

(22) PCT Filed: Aug. 24, 2015
(86) PCT No.: PCT/CN2015/087909

§ 371 Date: Sep. 21, 2015

(30) Foreign Application Priority Data
Aug. 3, 2015 (CN) 201510484324.1

(51) Int. Cl. G09G 3/3258; H01L 27/12; H01L 27/32; G09G 3/3266; G09G 3/3291

(52) U.S. Cl. CPC G09G 3/3258; G09G 3/3266; G09G 3/3291; H01L 27/3262; H01L 27/1255; H01L 27/1225; H01L 27/124; H01L 27/3276; G09G 2300/0819; G09G 2330/021

(57) ABSTRACT

The present invention provides an AMOLED pixel driving circuit and a pixel driving method. The AMOLED pixel driving circuit utilizing the 3T1C structure comprises: a first thin film transistor (T1), a second thin film transistor (T2), a third thin film transistor (T3), a storage capacitor (Cs) and an organic light emitting diode (OLED), and the second scan signal voltage (Vsel2) in introduced. The third thin film transistor (T3) provides initial low voltage level (Vini) of the data signal voltage (VData) to the source of the first thin film transistor (T1), i.e. the drive thin film transistor in the reset stage, which can effectively compensate the threshold voltage changes of the drive thin film transistor for diminishing the complexity of the power supply voltage signal.

### FIELD OF THE INVENTION

The present invention relates to a display technology field, and more particularly to an AMOLED pixel driving circuit and a pixel driving method.

### BACKGROUND OF THE INVENTION

The Organic Light Emitting Display (OLED) possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device.

The OLED can be categorized into two major types according to the driving methods, which are the Passive Matrix OLED (PMOLED) and the Active Matrix OLED (AMOLED), i.e. two types of the direct addressing and the Thin Film Transistor (TFT) matrix addressing. The AMOLED comprises pixels arranged in array and belongs to active display type, which has high lighting efficiency and is generally utilized for the large scale display devices of high resolution.

The AMOLED is a current driving element. When the electrical current flows through the organic light emitting diode, the organic light emitting diode emits light, and the brightness is determined according to the current flowing through the organic light emitting diode itself. Most of the present Integrated Circuits (IC) only transmit voltage signals. Therefore, the AMOLED pixel driving circuit needs to accomplish the task of converting the voltage signals into the current signals. The traditional AMOLED pixel driving circuit generally is 2T1C, which is a structure comprising two thin film transistors and one capacitor to convert the voltage into the current. However, the traditional 2T1C pixel driving circuit has no compensation function.

As shown in FIG. 1, which shows a 2T1C pixel driving circuit employed for AMOLED with compensation function according to prior art, comprising a first thin film transistor T10, a second thin film transistor T20 and a capacitor Cs. The first thin film transistor T10 is a drive thin film transistor, and the second thin film transistor T20 is a switch thin film transistor, and the capacitor Cs is a storage capacitor. Specifically, a gate of the second thin film transistor T20 is electrically coupled to a scan signal voltage Vsel, and a source is electrically coupled to a data signal voltage Vdata, and a drain is electrically coupled to a gate of the first thin film transistor T10 and one end of the capacitor Cs; a source of the first thin film transistor T10 is electrically coupled to a power supply voltage Vdd, and a drain is electrically coupled to an anode of the organic light emitting diode D; a cathode of the organic light emitting diode D is electrically coupled to an earth; the one end of the capacitor Cs is electrically coupled to the drain of the second thin film transistor T20, and the other end is electrically coupled to the source of the first thin film transistor T10.

Please refer to FIG. 2. FIG. 2 is a voltage level diagram of respective working stages and key nodes corresponding to FIG. 1. AS shown in FIG. 2, the working procedure of the 2T1C pixel driving circuit is divided into four stages, which are specifically introduced: 1, the reset stage S10: the scan signal voltage Vsel provides high voltage level to control the second thin film transistor T20 to be activated, and the data signal voltage VData provides a first reference voltage Vref1 to the gate of the first thin film transistor T10 through the second thin film transistor T20, i.e. the gate voltage Va of the first thin film transistor T10=Vref1, and the first thin film transistor T10 is activated, and the alternating current power supply voltage Vdd provides low voltage level Vdl, and then the source voltage Vb of the first thin film transistor=Vdl; 2, the threshold voltage detection stage S20: the scan signal voltage Vsel provides high voltage level to control the second thin film transistor T20 to be activated, and the data signal voltage VData provides a second reference voltage Vref2 to the gate of the first thin film transistor T10 through the second thin film transistor T20, and Vref2<Vref1, i.e. the gate voltage Va of the first thin film transistor T10=Vref2, and the first thin film transistor T10 is activated, and the alternating current power supply voltage Vdd provides high voltage level, and then the source voltage Vb of the first thin film transistor is raised to Vb=Vref2−Vth, and Vth is the threshold voltage of the first thin film transistor T10; 3, the threshold voltage compensation stage S30: the scan signal voltage Vsel provides high voltage level to control the second thin film transistor T20 to be activated, and the data signal voltage VData provides a display data signal voltage Vdata to the gate of the first thin film transistor T10 and the capacitor Cs through the second thin film transistor T20, i.e. the gate voltage Va of the first thin film transistor T10=Vdata, and the first thin film transistor T10 is activated, and the alternating current power supply voltage Vdd provides high voltage level, and then the source voltage Vb of the first thin film transistor is changed to Vb=Vref2−Vth+ΔV, and ΔV is an influence generated by the data signal high voltage level Vdata to the voltage of the source of the first thin film transistor T10; 4, the drive stage S40, the scan signal voltage Vsel provides low voltage level, and the second thin film transistor T20 is deactivated, and with the storage function of the capacitor Cs, the voltage of the gate of the second thin film transistor T20 still can be kept at the data signal voltage Va=Vdata to make that the first thin film transistor T10 to be in an activation state, and the voltage of the source of the first thin film transistor T10 is Vb=Vref2−Vth+ΔV, and the gate source voltage of the first thin film transistor T10 is Vgs=Va−Vb=Vdata−Vref2+Vth−ΔV, which can compensate the threshold voltage of the drive thin film transistor. However, drawbacks of complicated alternating current power supply voltage Vdd exists in the 2T1C pixel driving circuit shown in FIG. 1.

### SUMMARY OF THE INVENTION

An objective of the present invention is to provide an AMOLED pixel driving circuit, which can effectively compensate the threshold voltage changes of the drive thin film transistor for diminishing the complexity of the power supply voltage signal.

Another objective of the present invention is to provide an AMOLED pixel driving method, which can effectively compensate the threshold voltage changes of the drive thin film transistor for solving the problem of the power supply voltage signal complexity.

For realizing the aforesaid objectives, the present invention provides an AMOLED pixel driving circuit, comprising: a first thin film transistor, a second thin film transistor, a third thin film transistor, a storage capacitor and an organic light emitting diode;

a gate of the first thin film transistor is electrically coupled to a first node, and a drain is electrically coupled to a second node, and a drain is electrically coupled to a power supply voltage;

a gate of the second thin film transistor is electrically coupled to a first scan signal voltage, and a source is electrically coupled to a data signal voltage, and a drain is electrically coupled to the first node;

a gate of the third thin film transistor is electrically coupled to a second scan signal voltage, and a source is electrically coupled to the data signal voltage, and a drain is electrically coupled to the second node;

one end of the storage capacitor is electrically coupled to the first node, and the other end is electrically coupled to the second node;

an anode of the organic light emitting diode is electrically coupled to the second node, and the cathode is electrically coupled to the earth;

the first thin film transistor is a drive thin film transistor;

the power supply voltage Vdd is a constant high voltage.

All of the first thin film transistor, the second thin film transistor and the third thin film transistor are Low Temperature Poly-silicon thin film transistors, oxide semiconductor thin film transistors or amorphous silicon thin film transistors.

All of the first scan signal voltage, the second scan signal voltage and the data signal voltage are provided by an external sequence controller.

The first scan signal voltage, the second scan signal voltage and the data signal voltage are combined with one another, and correspond to a reset stage, a threshold voltage detection stage, a threshold voltage compensation stage and a drive stage one after another;

in the reset stage, the first scan signal voltage and the second scan signal voltage are high voltage levels, and the data signal voltage is initial low voltage level;

in the threshold voltage detection stage, the first scan signal voltage is high voltage level, and the second scan signal voltage is low voltage level, and the data signal voltage is reference high voltage level;

in the threshold voltage detection stage, the first scan signal voltage is high voltage level, and the second scan signal voltage is low voltage level, and the data signal voltage is data play data signal high voltage level;

in the drive stage, the first scan signal voltage and the second scan signal voltage are low voltage levels, and the data signal voltage is reference high voltage level. The display data signal high voltage level is higher than the reference high voltage level.

The present invention further provides an AMOLED pixel driving method, comprising steps of:

step 1, providing an AMOLED pixel driving circuit, comprising: a first thin film transistor, a second thin film transistor, a third thin film transistor, a storage capacitor and an organic light emitting diode;

a gate of the first thin film transistor is electrically coupled to a first node, and a drain is electrically coupled to a second node, and a drain is electrically coupled to a power supply voltage;

a gate of the second thin film transistor is electrically coupled to a first scan signal voltage, and a source is electrically coupled to a data signal voltage, and a drain is electrically coupled to the first node;

a gate of the third thin film transistor is electrically coupled to a second scan signal voltage, and a source is electrically coupled to the data signal voltage, and a drain is electrically coupled to the second node;

one end of the storage capacitor is electrically coupled to the first node, and the other end is electrically coupled to the second node;

an anode of the organic light emitting diode is electrically coupled to the second node, and the cathode is electrically coupled to the earth;

the first thin film transistor is a drive thin film transistor;

the power supply voltage is a constant high voltage;

step 2, entering a reset stage;

the first scan signal voltage and the second scan signal voltage provide high voltage levels, and the second, third thin film transistors are activated, and the data signal voltage provides initial low voltage level to be written into the first node, which is the gate of the first thin film transistor and the second node, which is the source of the first thin film transistor respectively through the second, third thin film transistors, and the first thin film transistor is deactivated;

step 3, entering a threshold voltage detection stage;

the first scan signal voltage provides high voltage level and the second scan signal voltage provides low voltage level, and the second thin film transistor is activated, and the third thin film transistor is deactivated, and the data signal voltage provides high voltage level to the first node, which is the gate of the first thin film transistor through the second thin film transistor, and the first thin film transistor is activated, and a voltage level of the second node, which is the source of the first thin film transistor is raised to Vref−Vth, wherein Vth is a threshold voltage of the first thin film transistor;

step 4, entering a threshold voltage compensation stage;

the first scan signal voltage provides high voltage level and the second scan signal voltage provides low voltage level, and the second thin film transistor is activated, and the third thin film transistor is deactivated, and the data signal voltage provides display data signal high voltage level to the first node, which is the gate of the first thin film transistor and the storage capacitor through the second thin film transistor, and the first thin film transistor is activated, the voltage level of the second node, which is the source of the first thin film transistor is changed to Vref−Vth+ΔV, wherein ΔV is an influence generated by the data signal high voltage level to the voltage of the source of the first thin film transistor, which is a voltage level of the second node;

step 5, entering a drive stage; the data signal voltage provides reference high voltage level, and the first scan signal voltage and the second scan signal voltage provide low voltage levels, and the second, third thin film transistors are deactivated, and with a storage function of the storage capacitor, a voltage level of the first node, which is the gate of the first thin film transistor can be continuously to be kept at display data signal high voltage level to make the first thin film transistor in an activation state; the voltage level of the second node, which is the source of the first thin film transistor remains to be Vref−Vth+ΔV;

the organic light emitting diode emits light, and a current flowing through the organic light emitting diode is irrelevant with the threshold voltage of the first thin film transistor.

All of the first thin film transistor, the second thin film transistor and the third thin film transistor are Low Temperature Poly-silicon thin film transistors, oxide semiconductor thin film transistors or amorphous silicon thin film transistors.

All of the first scan signal voltage, the second scan signal voltage and the data signal voltage are provided by an external sequence controller.

The display data signal high voltage level is higher than the reference high voltage level.

The present invention further provides an AMOLED pixel driving method, comprising steps of:

step 1, providing an AMOLED pixel driving circuit, comprising: a first thin film transistor, a second thin film transistor, a third thin film transistor, a storage capacitor and an organic light emitting diode;

a gate of the first thin film transistor is electrically coupled to a first node, and a drain is electrically coupled to a second node, and a drain is electrically coupled to a power supply voltage;

a gate of the second thin film transistor is electrically coupled to a first scan signal voltage, and a source is electrically coupled to a data signal voltage, and a drain is electrically coupled to the first node;

a gate of the third thin film transistor is electrically coupled to a second scan signal voltage, and a source is electrically coupled to the data signal voltage, and a drain is electrically coupled to the second node;

one end of the storage capacitor is electrically coupled to the first node, and the other end is electrically coupled to the second node;

an anode of the organic light emitting diode is electrically coupled to the second node, and the cathode is electrically coupled to the earth;

the first thin film transistor is a drive thin film transistor;

the power supply voltage is a constant high voltage;

step 2, entering a reset stage;

the first scan signal voltage and the second scan signal voltage provide high voltage levels, and the second, third thin film transistors are activated, and the data signal voltage provides initial low voltage level to be written into the first node, which is the gate of the first thin film transistor and the second node, which is the source of the first thin film transistor respectively through the second, third thin film transistors, and the first thin film transistor is deactivated;

step 3, entering a threshold voltage detection stage;

the first scan signal voltage provides high voltage level and the second scan signal voltage provides low voltage level, and the second thin film transistor is activated, and the third thin film transistor is deactivated, and the data signal voltage provides high voltage level to the first node, which is the gate of the first thin film transistor through the second thin film transistor, and the first thin film transistor is activated, and a voltage level of the second node, which is the source of the first thin film transistor is raised to Vref−Vth, wherein Vth is a threshold voltage of the first thin film transistor;

step 4, entering a threshold voltage compensation stage;

the first scan signal voltage provides high voltage level and the second scan signal voltage provides low voltage level, and the second thin film transistor is activated, and the third thin film transistor is deactivated, and the data signal voltage provides display data signal high voltage level to the first node, which is the gate of the first thin film transistor and the storage capacitor through the second thin film transistor, and the first thin film transistor is activated, the voltage level of the second node, which is the source of the first thin film transistor is changed to Vref−Vth+ΔV, wherein ΔV is an influence generated by the data signal high voltage level to the voltage of the source of the first thin film transistor, which is a voltage level of the second node;

step 5, entering a drive stage; the data signal voltage provides reference high voltage level, and the first scan signal voltage and the second scan signal voltage provide low voltage levels, and the second, third thin film transistors are deactivated, and with a storage function of the storage capacitor, a voltage level of the first node, which is the gate of the first thin film transistor can be continuously to be kept at display data signal high voltage level to make the first thin film transistor in an activation state; the voltage level of the second node, which is the source of the first thin film transistor remains to be Vref−Vth+ΔV;

the organic light emitting diode emits light, and a current flowing through the organic light emitting diode is irrelevant with the threshold voltage of the first thin film transistor;

wherein all of the first thin film transistor, the second thin film transistor and the third thin film transistor are Low Temperature Poly-silicon thin film transistors, oxide semiconductor thin film transistors or amorphous silicon thin film transistors;

wherein all of the first scan signal voltage, the second scan signal voltage and the data signal voltage are provided by an external sequence controller.

wherein the display data signal high voltage level is higher than the reference high voltage level.

The benefits of the present invention are: the AMOLED pixel driving circuit and pixel driving method provided by the present invention utilizes the pixel driving circuit of the 3T1C structure to compensate the threshold voltage of the driving thin film transistor in each pixel, which can effectively compensate the threshold voltage changes of the drive thin film transistor in each pixel to make the display brightness of the AMOLED more even and to raise the display quality; by introducing the second scan signal voltage so that the third thin film transistor provides initial low voltage level of the data signal voltage to the source of the drive thin film transistor in the reset stage, which can diminish the complexity of the power supply voltage signal.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a circuit diagram of 2T1C pixel driving circuit employed for AMOLED according to prior art;

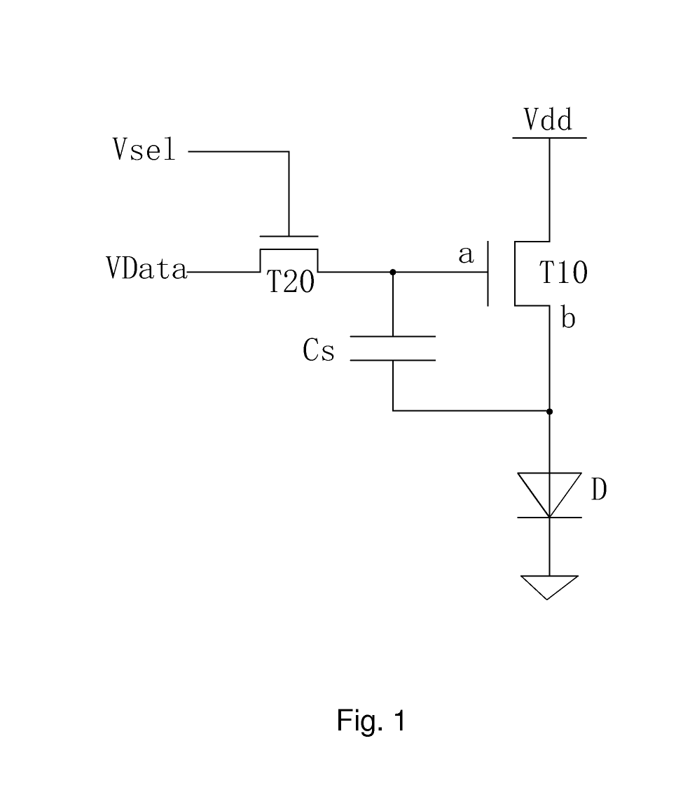

FIG. 2 is a voltage level diagram of respective working stages and key nodes of a 2T1C pixel driving circuit employed for AMOLED corresponding to FIG. 1;

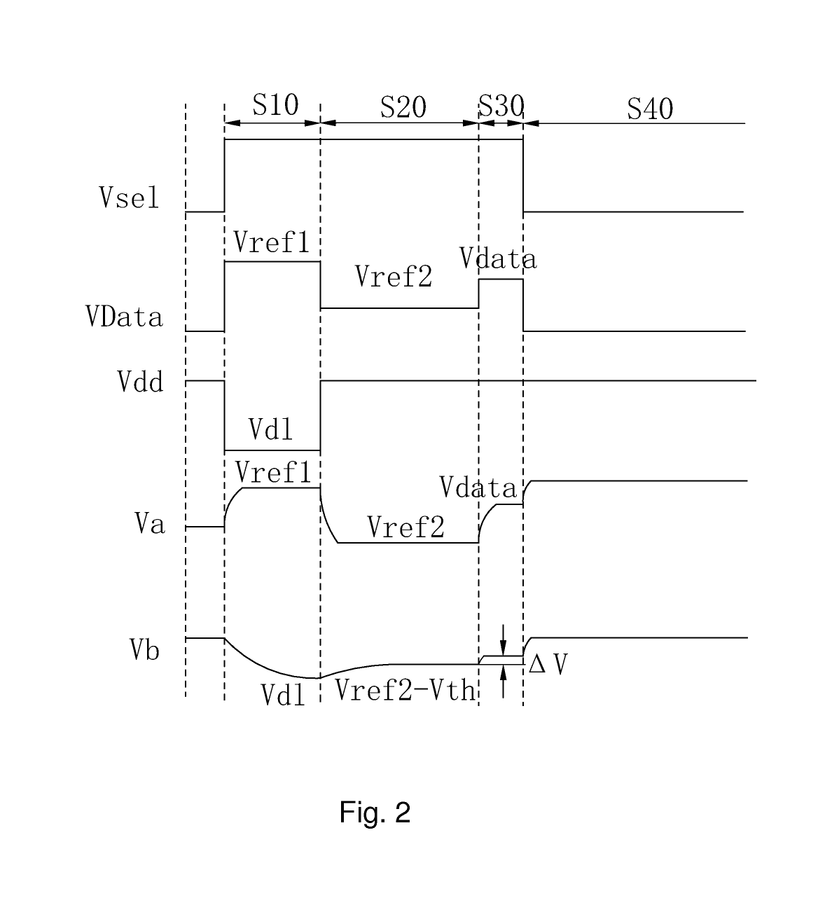

FIG. 3 is a circuit diagram of an AMOLED pixel driving circuit according to present invention;

FIG. 4 is a sequence diagram of an AMOLED pixel driving circuit according to the present invention;

FIG. 5 is a voltage level diagram showing respective working stages and key nodes of an AMOLED pixel driving circuit according to present invention;

FIG. 6 is a diagram of the step 2 of an AMOLED pixel driving method according to the present invention;

FIG. 7 is a diagram of the step 3 of an AMOLED pixel driving method according to the present invention;

FIG. 8 is a diagram of the step 4 of an AMOLED pixel driving method according to the present invention;

FIG. 9 is a diagram of the step 5 of an AMOLED pixel driving method according to the present invention;

FIG. 10 is a simulation diagram of the corresponding current flowing through the OLED as the threshold voltage of the drive thin film transistor in the traditional 2T1C pixel driving circuit of no compensation drifts;

FIG. 11 is a simulation diagram of the corresponding current flowing through the OLED as the threshold voltage of the drive thin film transistor in the present invention drifts.

### DETAILED DESCRIPTION OF PREFERRED EMBODIMENTS

For better explaining the technical solution and the effect of the present invention, the present invention will be further described in detail with the accompanying drawings and the specific embodiments.

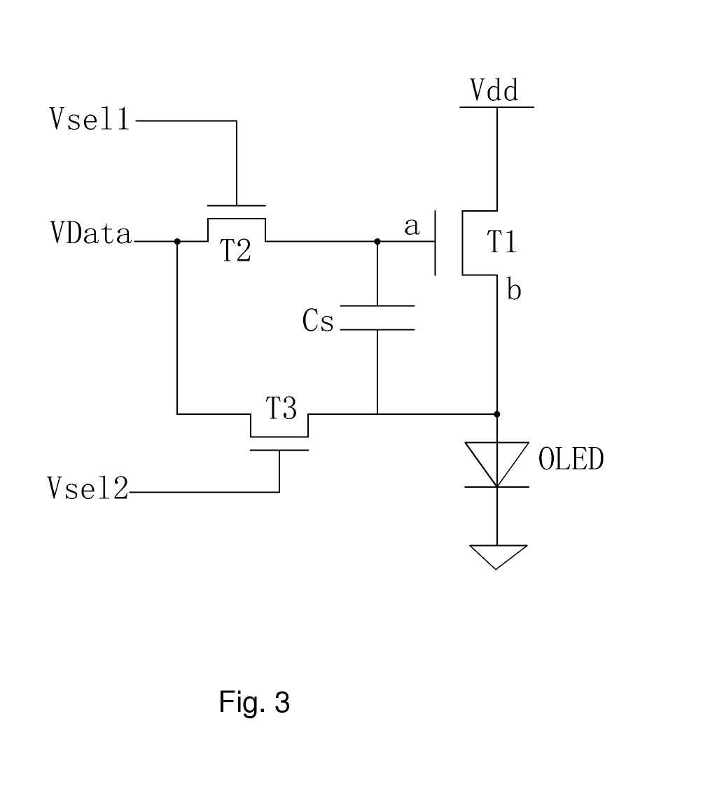

Please refer to FIG. 3. The present invention first provides an AMOLED pixel driving circuit, and the AMOLED pixel driving circuit comprises: a first thin film transistor T1, a second thin film transistor T2, a third thin film transistor T3, a storage capacitor Cs and an organic light emitting diode OLED.

a gate of the first thin film transistor T1 is electrically coupled to a first node a, and a source is electrically coupled to a second node b, and a drain is electrically coupled to a power supply voltage Vdd;

a gate of the second thin film transistor T2 is electrically coupled to a first scan signal voltage Vsel1, and a source is electrically coupled to a data signal voltage VData, and a drain is electrically coupled to the first node a;

a gate of the third thin film transistor T3 is electrically coupled to a second scan signal voltage Vsel2, and a source is electrically coupled to the data signal voltage VData, and a drain is electrically coupled to the second node b;

one end of the storage capacitor Cs is electrically coupled to the first node a, and the other end is electrically coupled to the second node b;

an anode of the organic light emitting diode OLED is electrically coupled to the second node b, and the cathode is electrically coupled to the earth;

The first thin film transistor T1 is a drive thin film transistor.

Specifically, all of the first thin film transistor T1, the second thin film transistor T2 and the third thin film transistor T3 are Low Temperature Poly-silicon thin film transistors, oxide semiconductor thin film transistors or amorphous silicon thin film transistors.

All of the first scan signal voltage Vsel1, the second scan signal voltage Vsel2 and the data signal voltage VData are provided by an external sequence controller.

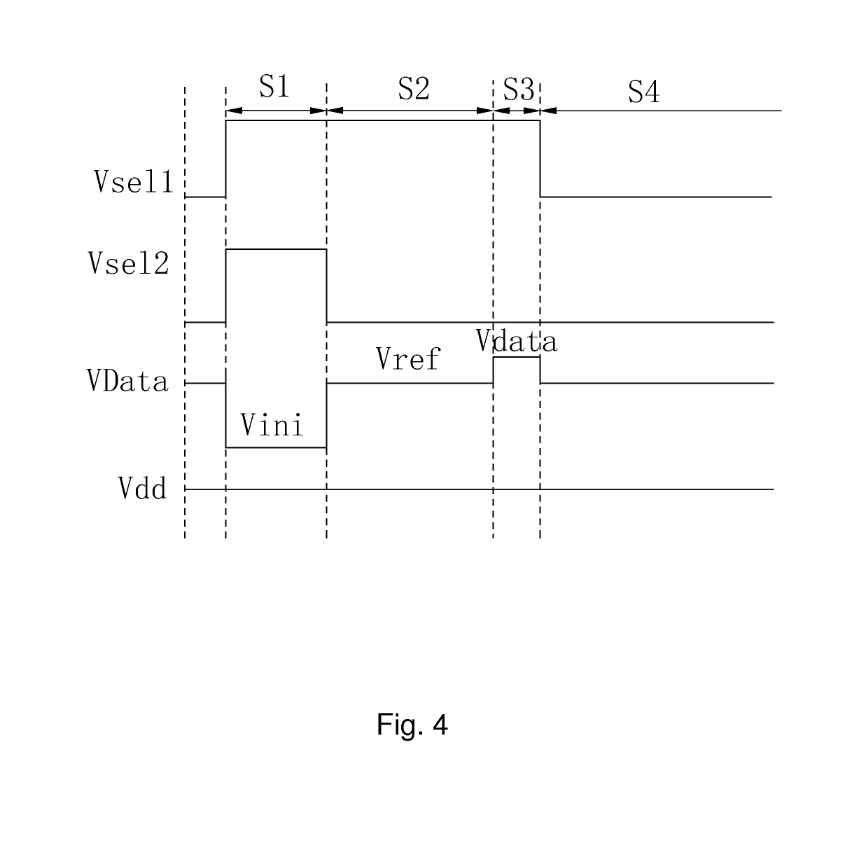

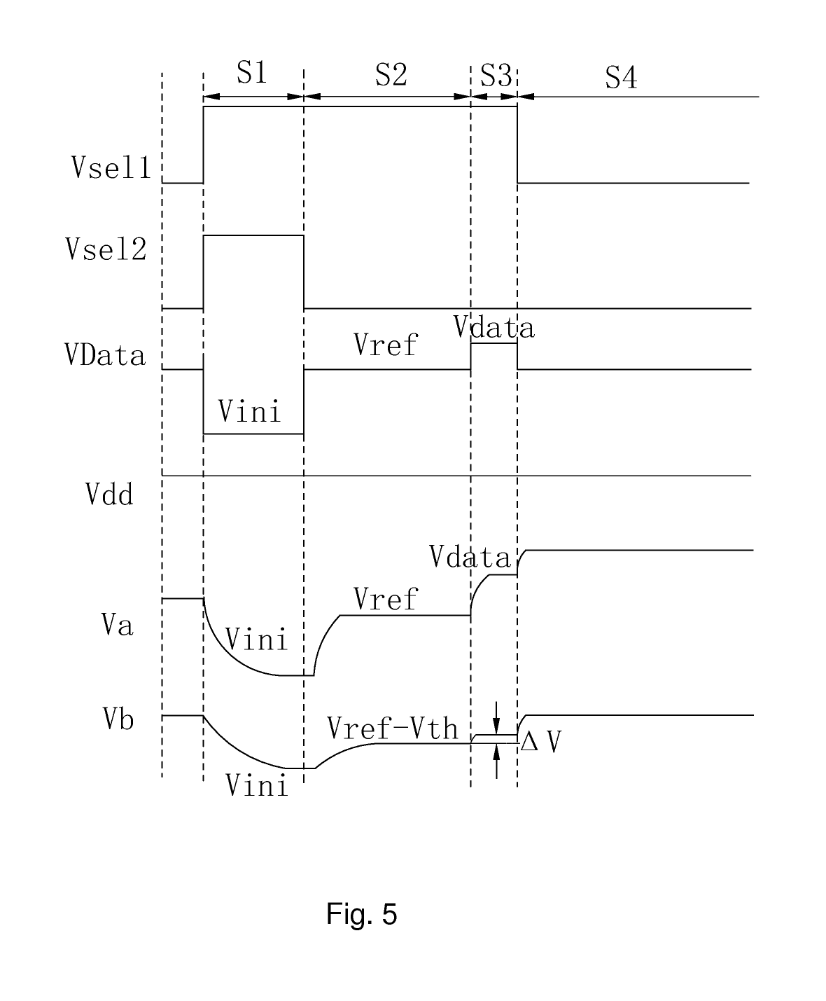

Furthermore, referring to FIG. 4 and FIG. 5, the power supply voltage Vdd is a constant high voltage, and the first scan signal voltage Vsel1, the second scan signal voltage Vsel2 and the data signal voltage VData are combined with one another, and correspond to a reset stage S1, a threshold voltage detection stage S2, a threshold voltage compensation stage S3 and a drive stage S4 one after another.

In the reset stage S1, the first scan signal voltage Vsel1 and the second scan signal voltage Vsel2 are high voltage levels, and the data signal voltage VData is initial low voltage level Vini.

In the threshold voltage detection stage S2, the first scan signal voltage Vsel1 is high voltage level, and the second scan signal voltage Vsel2 is low voltage level, and the data signal voltage VData is reference high voltage level Vref.

In the threshold voltage detection stage S3, the first scan signal voltage Vsel1 is high voltage level, and the second scan signal voltage Vsel2 is low voltage level, and the data signal voltage VData is data play data signal high voltage level Vdata.

In the drive stage S4, the first scan signal voltage Vsel1 and the second scan signal voltage Vsel2 are low voltage levels, and the data signal voltage VData is reference high voltage level Vref.

The first scan signal voltage Vsel1 is employed to control the on and off of the second thin film transistor T2; the storage capacitor Cs is employed to store the data signal voltage VData; the second scan signal voltage Vsel2 is employed to control the on and off of the third thin film transistor T3 to realize providing initial low voltage Vini to the second node b, i.e. the source of the first thin film transistor T1 in the reset stage S1. The display data signal high voltage level Vdata is higher than the reference high voltage level Vref.

The AMOLED pixel driving circuit can diminish the complexity of the power supply voltage signal, and effectively compensate the threshold voltage changes of the first thin film transistor T1, i.e. the drive thin film transistor in each pixel to make the display brightness of the AMOLED more even and to raise the display quality.

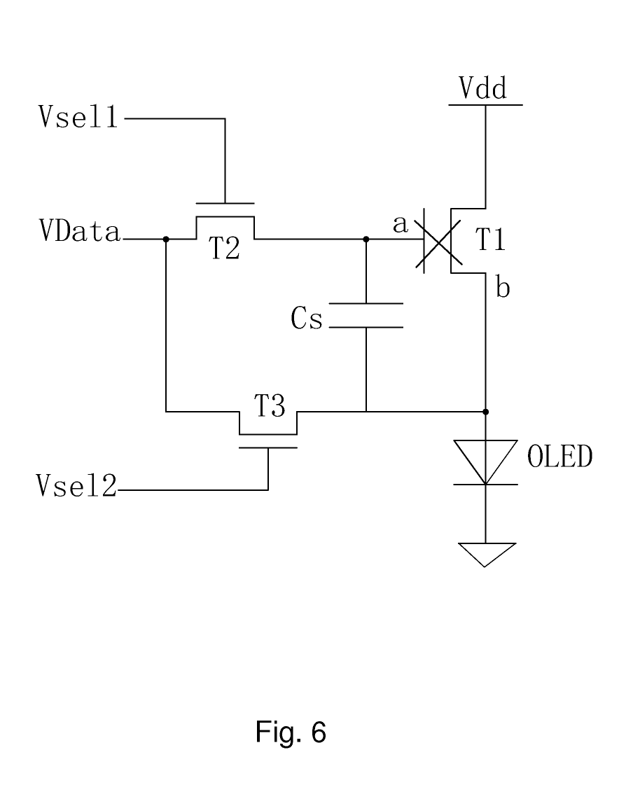

Please refer from FIG. 6 to FIG. 9 in conjunction with FIG. 4 and FIG. 5. On the basis of the aforesaid AMOLED pixel driving circuit, the present invention further provides an AMOLED pixel driving method, comprising steps of:

step 1, providing an AMOLED pixel driving circuit utilizing the 3T1C structure as shown in the aforesaid FIG. 3, wherein the power supply voltage Vdd is a constant high voltage all the time.

The description of the circuit is not repeated here.

step 2, referring FIG. 6 in combination with FIG. 4 and FIG. 5, first, entering the reset stage S1.

The first scan signal voltage Vsel1 and the second scan signal voltage Vsel2 provide high voltage levels, and the second, third thin film transistors T2, T3 are activated, and the data signal voltage VData provides initial low voltage level Vini to be written into the first node a, which is the gate of the first thin film transistor T1 and the second node b, which is the source of the first thin film transistor T1 respectively through the second, third thin film transistors T2, T3, and the first thin film transistor T1 is deactivated.

In the reset stage S1:

Vg=Va=Vini

Vs=Vb=Vini

wherein Vg represents the gate voltage level of the first thin film transistor T1, and Va represents the voltage level of the first node a, and Vs represents the source voltage level of the first thin film transistor T1, and Vb represents the voltage level of the second node b.

The organic light emitting diode OLED does not emit light.

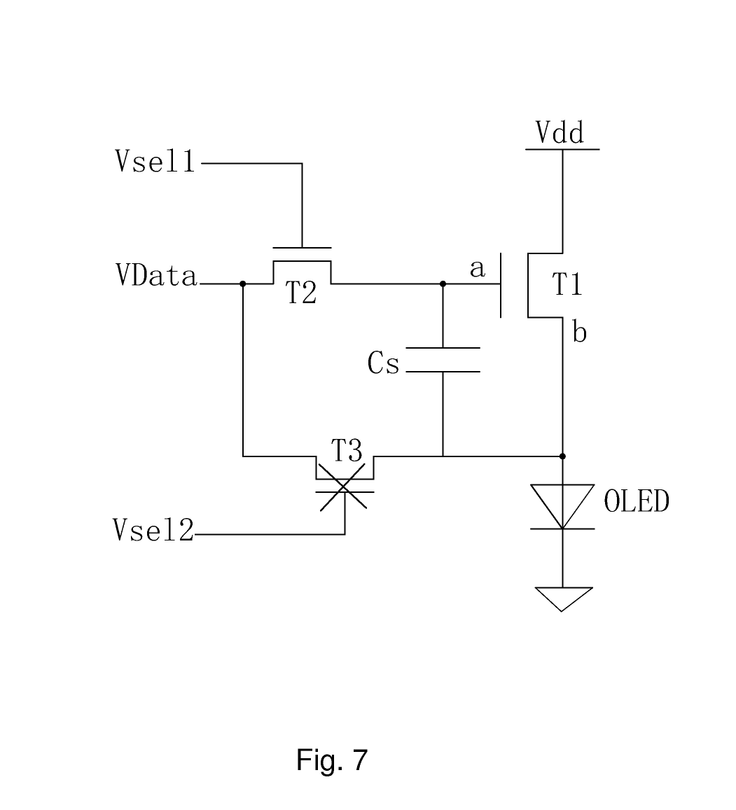

step 3, referring to FIG. 7 in combination with FIG. 4 and FIG. 5, entering the threshold voltage detection stage S2.

The first scan signal voltage Vsel1 provides high voltage level and the second scan signal voltage Vsel2 provides low voltage level, and the second thin film transistor T2 is activated, and the third thin film transistor T3 is deactivated, and the data signal voltage VData provides high voltage level Vref to the first node a, which is the gate of the first thin film transistor T1 through the second thin film transistor T2, and the first thin film transistor T1 is activated, and a voltage level of the second node b, which is the source of the first thin film transistor T1 is raised to Vref-Vth, wherein Vth is a threshold voltage of the first thin film transistor T1.

In the threshold voltage detection stage S2:

Vg=Va=Vref

Vs=Vb=Vref−Vth

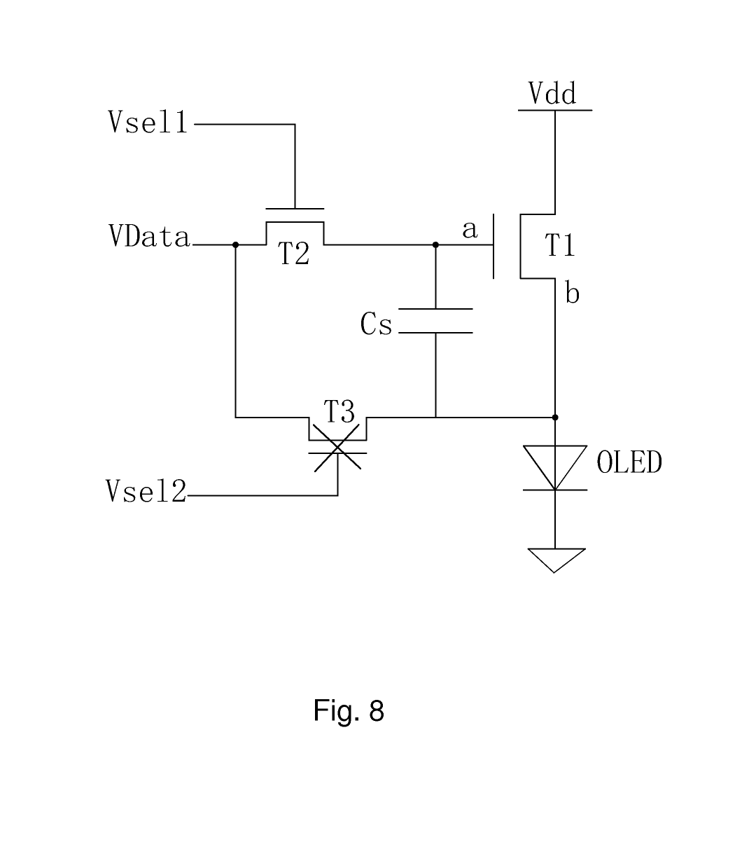

step 4, referring to FIG. 8 in combination with FIG. 4 and FIG. 5, entering the threshold voltage compensation stage S3.

The first scan signal voltage Vsel1 provides high voltage level and the second scan signal voltage Vsel2 provides low voltage level, and the second thin film transistor T2 is activated, and the third thin film transistor T3 is deactivated, and the data signal voltage VData provides display data signal high voltage level Vdata to the first node a, which is the gate of the first thin film transistor T1 and the storage capacitor Cs through the second thin film transistor T2, and the first thin film transistor T1 is activated, the voltage level of the second node b, which is the source of the first thin film transistor T1 is changed to Vref−Vth+ΔV, wherein ΔV is an influence generated by the data signal high voltage level Vdata to the voltage of the source of the first thin film transistor T1, which is a voltage level of the second node b.

In the threshold voltage compensation stage S3:

Vg=Va=Vdata

Vs=Vb=Vref−Vth+ΔV

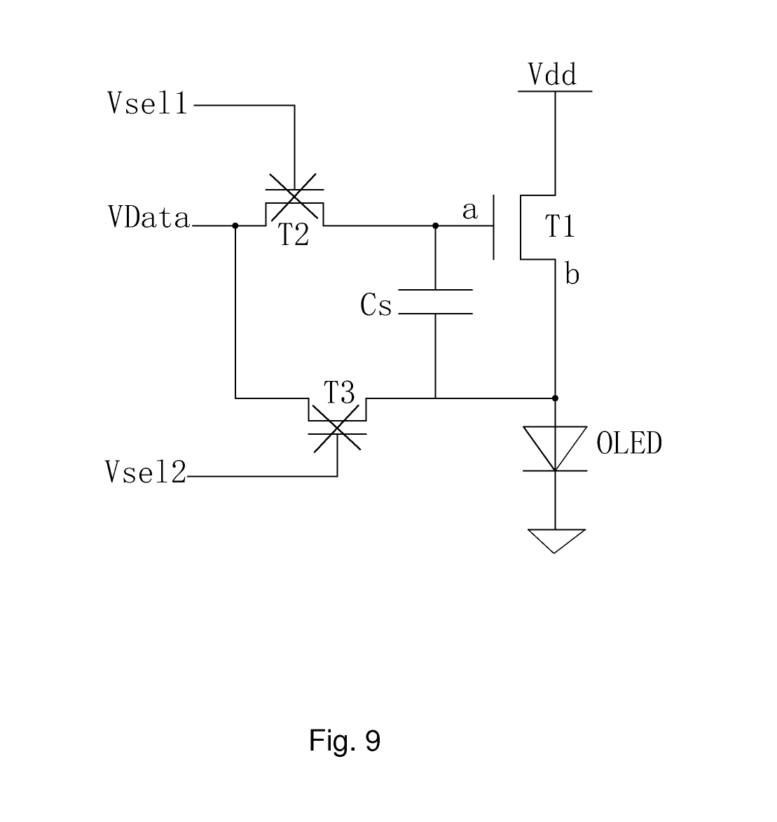

step 5, referring to FIG. 9 in combination with FIG. 4 and FIG. 5, entering the drive stage S4.

The data signal voltage VData provides reference high voltage level Vref, and the first scan signal voltage Vsel1 and the second scan signal voltage Vsel2 provide low voltage levels, and the second, third thin film transistors T2, T3 are deactivated, and with a storage function of the storage capacitor Cs, the first thin film transistor T1 is in an activation state, and a voltage level of the first node a, which is the gate of the first thin film transistor T1 can be continuously to be kept at:

Vg=Va=Vdata;

the voltage level of the second node b, which is the source of the first thin film transistor T1 remains to be:

Vs=Vb=Vref−Vth−ΔV;

Furthermore, as known, the formula of calculating the current flowing through the organic light emitting diode OLED is:

I_{OLED}=½Cox(μW/L)(Vgs−Vth)² (1)

wherein IOLED is the current of the organic light emitting diode OLED, and μ is the carrier mobility of drive thin film transistor, and W and L respectively are the width and the length of the channel of the drive thin film transistor, and Vgs is the voltage between the gate and the source of the drive thin film transistor, and Vth is the threshold voltage of the drive thin film transistor. In the present invention, the threshold voltage Vth of the drive thin film transistor, i.e. the threshold voltage Vth of the first thin film transistor T1; Vgs is the difference between the gate voltage Vg and the source voltage Vs of the first thin film transistor T1, which is:

Vgs=Vg−Vs=Vdata−(Vref−Vth+ΔV)=Vdata−Vref+Vth−ΔV (2)

the equation (2) is substituted into equation (1) to derive:

I_{OLED}=½Cox(ρW/L)(Vdata−Vref+Vth−ΔV−Vth)²=½Cox(μW/L)(Vdata−Vref−ΔV)²

Consequently, the current IOLED flowing through the organic light emitting diode OLED is irrelevant with the threshold voltage of the first thin film transistor T1 to realize the compensation function. The organic light emitting diode OLED emits light, and the current IOLED flowing through the organic light emitting diode OLED is irrelevant with the threshold voltage of the first thin film transistor T1.

In the AMOLED pixel driving method of the present invention, because the power supply voltage Vdd is a constant high voltage all the time, the power supply voltage can be simplified and the complexity is tremendously diminished in comparison with prior art.

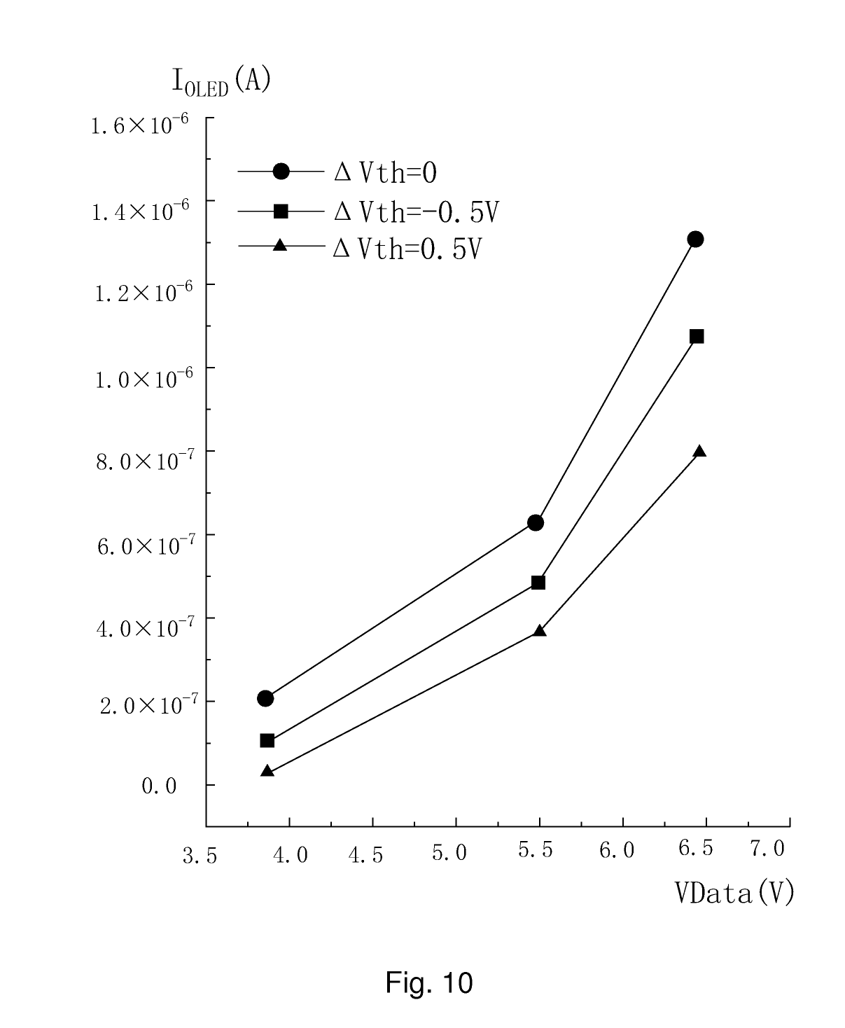

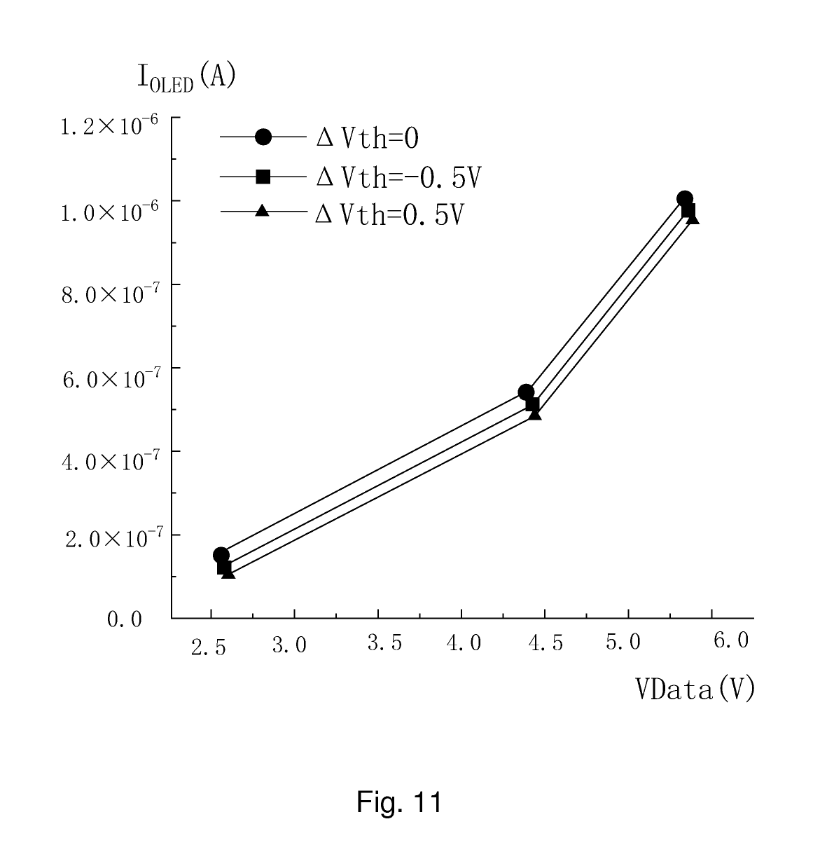

Please refer to FIG. 10, FIG. 11. FIG. 10 and FIG. 11 respectively are simulation diagrams of the current flowing through the organic light emitting diode as the threshold voltage of the drive thin film transistor in the traditional 2T1C pixel driving circuit of no compensation, i.e. the first thin film transistor T1 drifts 0V, +0.5V, −0.5V according to prior art and the present invention. By comparing two figures, it can be seen that the change of the current flowing through the organic light emitting diode in the circuit according to the present invention is obviously smaller than the change of the current flowing through the organic light emitting diode in the traditional 2T1C pixel driving circuit of no compensation. Therefore, the present invention effectively compensates the threshold voltage of the drive thin film transistor for ensuring the light emitting stability of the organic light emitting diode OLED to make the brightness of the AMOLED more even and raise the display quality.

In conclusion, the AMOLED pixel driving circuit and pixel driving method of the present invention utilizes the pixel driving circuit of the 3T1C structure to compensate the threshold voltage of the driving thin film transistor in each pixel, which can effectively compensate the threshold voltage changes of the drive thin film transistor in each pixel to make the display brightness of the AMOLED more even and to raise the display quality; by introducing the second scan signal voltage so that the third thin film transistor provides initial low voltage level of the data signal voltage to the source of the drive thin film transistor in the reset stage, which can diminish the complexity of the power supply voltage signal.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An AMOLED pixel driving circuit, comprising: a first thin film transistor, a second thin film transistor, a third thin film transistor, a storage capacitor and an organic light emitting diode;
a gate of the first thin film transistor is electrically coupled to a first node, and a drain is electrically coupled to a second node, and a drain is electrically coupled to a power supply voltage;
a gate of the second thin film transistor is electrically coupled to a first scan signal voltage, and a source is electrically coupled to a data signal voltage, and a drain is electrically coupled to the first node;
a gate of the third thin film transistor is electrically coupled to a second scan signal voltage, and a source is electrically coupled to the data signal voltage, and a drain is electrically coupled to the second node;
one end of the storage capacitor is electrically coupled to the first node, and the other end is electrically coupled to the second node;
an anode of the organic light emitting diode is electrically coupled to the second node, and the cathode is electrically coupled to the earth;
the first thin film transistor is a drive thin film transistor;
the power supply voltage is a constant high voltage.

2. The AMOLED pixel driving circuit according to claim 1, wherein all of the first thin film transistor, the second thin film transistor and the third thin film transistor are Low Temperature Poly-silicon thin film transistors, oxide semiconductor thin film transistors or amorphous silicon thin film transistors.

3. The AMOLED pixel driving circuit according to claim 1, wherein all of the first scan signal voltage, the second scan signal voltage and the data signal voltage are provided by an external sequence controller.

4. The AMOLED pixel driving circuit according to claim 1, wherein the first scan signal voltage, the second scan signal voltage and the data signal voltage are combined with one another, and correspond to a reset stage, a threshold voltage detection stage, a threshold voltage compensation stage and a drive stage one after another;
in the reset stage, the first scan signal voltage and the second scan signal voltage are high voltage levels, and the data signal voltage is initial low voltage level;
in the threshold voltage detection stage, the first scan signal voltage is high voltage level, and the second scan signal voltage is low voltage level, and the data signal voltage is reference high voltage level;
in the threshold voltage detection stage, the first scan signal voltage is high voltage level, and the second scan signal voltage is low voltage level, and the data signal voltage is data play data signal high voltage level;
in the drive stage, the first scan signal voltage and the second scan signal voltage are low voltage levels, and the data signal voltage is reference high voltage level.

5. The AMOLED pixel driving circuit according to claim 4, wherein the display data signal high voltage level is higher than the reference high voltage level.

6. An AMOLED pixel driving method, comprising steps of:
step 1, providing an AMOLED pixel driving circuit, comprising: a first thin film transistor, a second thin film transistor, a third thin film transistor, a storage capacitor and an organic light emitting diode;
a gate of the first thin film transistor is electrically coupled to a first node, and a drain is electrically coupled to a second node, and a drain is electrically coupled to a power supply voltage;
a gate of the second thin film transistor is electrically coupled to a first scan signal voltage, and a source is electrically coupled to a data signal voltage, and a drain is electrically coupled to the first node;
a gate of the third thin film transistor is electrically coupled to a second scan signal voltage, and a source is electrically coupled to the data signal voltage, and a drain is electrically coupled to the second node;
one end of the storage capacitor is electrically coupled to the first node, and the other end is electrically coupled to the second node;
an anode of the organic light emitting diode is electrically coupled to the second node, and the cathode is electrically coupled to the earth;
the first thin film transistor is a drive thin film transistor;
the power supply voltage is a constant high voltage;
step 2, entering a reset stage;
the first scan signal voltage and the second scan signal voltage provide high voltage levels, and the second, third thin film transistors are activated, and the data signal voltage provides initial low voltage level to be written into the first node, which is the gate of the first thin film transistor and the second node, which is the source of the first thin film transistor respectively through the second, third thin film transistors, and the first thin film transistor is deactivated;
step 3, entering a threshold voltage detection stage;
the first scan signal voltage provides high voltage level and the second scan signal voltage provides low voltage level, and the second thin film transistor is activated, and the third thin film transistor is deactivated, and the data signal voltage provides high voltage level to the first node, which is the gate of the first thin film transistor through the second thin film transistor, and the first thin film transistor is activated, and a voltage level of the second node, which is the source of the first thin film transistor is raised to Vref-Vth, wherein Vth is a threshold voltage of the first thin film transistor;
step 4, entering a threshold voltage compensation stage;
the first scan signal voltage provides high voltage level and the second scan signal voltage provides low voltage level, and the second thin film transistor is activated, and the third thin film transistor is deactivated, and the data signal voltage provides display data signal high voltage level to the first node, which is the gate of the first thin film transistor and the storage capacitor through the second thin film transistor, and the first thin film transistor is activated, the voltage level of the second node, which is the source of the first thin film transistor is changed to Vref−Vth+ΔV, wherein ΔV is an influence generated by the data signal high voltage level to the voltage of the source of the first thin film transistor, which is a voltage level of the second node;
step 5, entering a drive stage; the data signal voltage provides reference high voltage level, and the first scan signal voltage and the second scan signal voltage provide low voltage levels, and the second, third thin film transistors are deactivated, and with a storage function of the storage capacitor, a voltage level of the first node, which is the gate of the first thin film transistor can be continuously to be kept at display data signal high voltage level to make the first thin film transistor in an activation state; the voltage level of the second node, which is the source of the first thin film transistor remains to be Vref−Vth+ΔV;
the organic light emitting diode emits light, and a current flowing through the organic light emitting diode is irrelevant with the threshold voltage of the first thin film transistor.

7. The AMOLED pixel driving method according to claim 6, wherein all of the first thin film transistor, the second thin film transistor and the third thin film transistor are Low Temperature Poly-silicon thin film transistors, oxide semiconductor thin film transistors or amorphous silicon thin film transistors.

8. The AMOLED pixel driving method according to claim 6, wherein all of the first scan signal voltage, the second scan signal voltage and the data signal voltage are provided by an external sequence controller.

9. The AMOLED pixel driving method according to claim 6, wherein the display data signal high voltage level is higher than the reference high voltage level.

10. An AMOLED pixel driving method, comprising steps of:
step 1, providing an AMOLED pixel driving circuit, comprising: a first thin film transistor, a second thin film transistor, a third thin film transistor, a storage capacitor and an organic light emitting diode;
a gate of the first thin film transistor is electrically coupled to a first node, and a drain is electrically coupled to a second node, and a drain is electrically coupled to a power supply voltage;
a gate of the second thin film transistor is electrically coupled to a first scan signal voltage, and a source is electrically coupled to a data signal voltage, and a drain is electrically coupled to the first node;
a gate of the third thin film transistor is electrically coupled to a second scan signal voltage, and a source is electrically coupled to the data signal voltage, and a drain is electrically coupled to the second node;
one end of the storage capacitor is electrically coupled to the first node, and the other end is electrically coupled to the second node;
an anode of the organic light emitting diode is electrically coupled to the second node, and the cathode is electrically coupled to the earth;
the first thin film transistor is a drive thin film transistor;
the power supply voltage is a constant high voltage;
step 2, entering a reset stage;
the first scan signal voltage and the second scan signal voltage provide high voltage levels, and the second, third thin film transistors are activated, and the data signal voltage provides initial low voltage level to be written into the first node, which is the gate of the first thin film transistor and the second node, which is the source of the first thin film transistor respectively through the second, third thin film transistors, and the first thin film transistor is deactivated;
step 3, entering a threshold voltage detection stage;
the first scan signal voltage provides high voltage level and the second scan signal voltage provides low voltage level, and the second thin film transistor is activated, and the third thin film transistor is deactivated, and the data signal voltage provides high voltage level to the first node, which is the gate of the first thin film transistor through the second thin film transistor, and the first thin film transistor is activated, and a voltage level of the second node, which is the source of the first thin film transistor is raised to Vref-Vth, wherein Vth is a threshold voltage of the first thin film transistor;
step 4, entering a threshold voltage compensation stage;
the first scan signal voltage provides high voltage level and the second scan signal voltage provides low voltage level, and the second thin film transistor is activated, and the third thin film transistor is deactivated, and the data signal voltage provides display data signal high voltage level to the first node, which is the gate of the first thin film transistor and the storage capacitor through the second thin film transistor, and the first thin film transistor is activated, the voltage level of the second node, which is the source of the first thin film transistor is changed to Vref−Vth+ΔV, wherein ΔV is an influence generated by the data signal high voltage level to the voltage of the source of the first thin film transistor, which is a voltage level of the second node;
step 5, entering a drive stage; the data signal voltage provides reference high voltage level, and the first scan signal voltage and the second scan signal voltage provide low voltage levels, and the second, third thin film transistors are deactivated, and with a storage function of the storage capacitor, a voltage level of the first node, which is the gate of the first thin film transistor can be continuously to be kept at display data signal high voltage level to make the first thin film transistor in an activation state; the voltage level of the second node, which is the source of the first thin film transistor remains to be Vref−Vth+ΔV;
the organic light emitting diode emits light, and a current flowing through the organic light emitting diode is irrelevant with the threshold voltage of the first thin film transistor;
wherein all of the first thin film transistor, the second thin film transistor and the third thin film transistor are Low Temperature Poly-silicon thin film transistors, oxide semiconductor thin film transistors or amorphous silicon thin film transistors;
wherein all of the first scan signal voltage, the second scan signal voltage and the data signal voltage are provided by an external sequence controller.
wherein the display data signal high voltage level is higher than the reference high voltage level.
